(19) United States
(12) Patent Application Publication
(10) Pub. No.: US 2012/0074969 A1
(43) Pub. Date: Mar. 29, 2012

(54) COUPON HOLDER FOR CORROSION MEASUREMENT

(75) Inventors: Ricky Eugene Snelling, Tulsa, OK (US); Donald Ray Engelbert, Copan, OK (US)

(73) Assignee: CONOCOPHILLIPS COMPANY, Houston, TX (US)

(21) Appl. No.: 13/236,260

(22) Filed: Sep. 19, 2011

Related U.S. Application Data
(60) Provisional application No. 61/385,852, filed on Sep. 23, 2010.

(51) Int. Cl. G01R 27/08; G01N 17/00

(52) U.S. Cl. 324/700; 422/53

(57) ABSTRACT

A non-metallic coupon holder assembly comprising a non-metallic support structure and a plurality of coupon holders. The pluralities of coupon holders are disposed throughout the non-metallic support structure wherein the pluralities of coupon holders are designed to secure a metal coupon on at least two edges.

### CROSS-REFERENCE TO RELATED APPLICATIONS

This application is a non-provisional application which claims benefit under 35 USC §119(e) to U.S. Provisional Application Ser. No. 61/385,852 filed Sep. 23, 2010, entitled “Improved Coupon Holder for Corrosion Measurement”, which is incorporated herein in its entirety.

### TECHNICAL FIELD

An apparatus for eliminating galvanic corrosion, random positioning of coupons, and variable coupon motion in corrosion measurement experiments.

### BACKGROUND OF THE INVENTION

Corrosion is a constant problem in the design, operation and maintenance of refineries, petrochemical plants and gas processing facilities. In an effort to understand the effects of corrosion, corrosion measurement experiments are performed on various metals and other materials in the presence of hydrocarbon fluids. However, traditional corrosion experiments fail to address potential pitfalls in the experimental apparatus for measuring corrosion. These design defects contribute to the corrosion measurements and cause significant experimental errors in the corrosion data. The experimental errors include galvanic corrosion due to metal to metal contact points on coupons, and corrosion enhancement (or inhibition) due to random positioning of coupons in the stirred reaction fluid and/or physical movement of coupons in the hydrocarbon fluid. These errors, when applied to hydrocarbon process design, can interfere with and can result in the selection of more costly corrosion resistant materials for processing equipment.

Accordingly, a coupon holder is needed to eliminate holder-related galvanic corrosion, random positioning of coupons, and variable coupon motion in corrosion measurement experiments.

### SUMMARY OF THE INVENTION

A non-metallic coupon holder assembly comprising a non-metallic support structure and a plurality of coupon holders. The pluralities of coupon holders are disposed throughout the non-metallic support structure wherein the pluralities of coupon holders are designed to secure a metal coupon on at least two edges.

In an alternate embodiment the apparatus also discloses a non-metallic coupon holder assembly made of quartz. The non-metallic coupon holder assembly has a non-metallic support structure and a plurality of coupon holders disposed throughout the non-metallic support structure. The plurality of coupon holders are evenly spaced along the non-metallic support structure and are designed to secure both the top edge of the metal coupon and the bottom edge of the metal coupon. The coupon holders are also designed to have a pair of ridges spaced evenly apart at a distance capable of accommodating the thickness of the metal coupon. In this embodiment the non-metallic coupon holder assembly is also multi-level with a plurality of coupon holders disposed throughout the non-metallic support structure on each level.

In yet another embodiment a method is taught that inserts a metal coupon into a non-metallic coupon holder assembly. The non-metallic coupon holder assembly comprises a non-metallic support structure and a plurality of coupon holders. The pluralities of coupon holders are disposed throughout the non-metallic support structure wherein the pluralities of coupon holders are designed to secure a metal coupon on at least two edges.

The metal coupon is then subjecting to a corrosion test for a specified period of time. A corrosion rate of the metal coupon is then measured by calculating the weight loss of the metal coupon over the specified period of time.

These and other objects, features, and advantages will become apparent as reference is made to the following detailed description, preferred embodiments, and examples, given for the purpose of disclosure, and taken in conjunction with the accompanying drawings and appended claims.

### BRIEF DESCRIPTION OF THE DRAWINGS

For a further understanding of the nature and objects of the present inventions, reference should be made to the following detailed disclosure, taken in conjunction with the accompanying drawings, in which like parts are given like reference numerals, and wherein:

FIG. 1 is a schematic of an upper end view of a coupon holder assembly in a corrosion vessel;

FIG. 2 is a schematic of a partial side view of a coupon holder assembly in a corrosion vessel;

FIG. 3 is a schematic of an elevated side view of a metal corrosion coupon;

FIG. 4 is a photograph of an elevated side view of a prototype coupon holder assembly in a corrosion vessel, showing an elevated side view of the base and a pair of reactor feed lines.

### DETAILED DESCRIPTION OF PREFERRED EMBODIMENTS OF THE INVENTIONS

The following detailed description of various embodiments of the present invention references the accompanying drawings, which illustrate specific embodiments in which the invention can be practiced. While the illustrative embodiments of the invention have been described with particularity, it will be understood that various other modifications will be apparent to and can be readily made by those skilled in the art without departing from the spirit and scope of the invention. Accordingly, it is not intended that the scope of the claims appended hereto to be limited to the examples and descriptions set forth herein but rather that the claims be construed as encompassing all the features of patentable novelty which reside in the present invention, including all features which would be treated as equivalents thereof by those skilled in the art to which the invention pertains. Therefore, the scope of the present invention is defined only by the appended claims, along with the full scope of equivalents to which such claims are entitled.

Corrosion measurement (and actions identified to remedy corrosion rates) allows for optimization of plant operation cost and life-cycle costs associated with the operation. A common corrosion measurement method includes a corrosion coupon (weight loss) technique. The weight loss technique involves exposing a specimen of a material (coupon) to a process fluid and/or environment for a given period of time, and then removing the coupon for analysis. In particular, the weight loss of the coupon is determined for the period. The corrosion rate is expressed as weight loss per time period.

The technique is quite versatile because coupons can be fabricated from any commercially available material, and, further the coupons can be made in appropriate shapes to study a variety of corrosion phenomena. The phenomena include stress-assisted corrosion, galvanic corrosion, differential aeration and heat affected zones.

In a typical corrosion measurement experiment in both a refinery and the lab, the coupons are initially weighed, and then subjected to the process fluid and/or environment for a given test period. A wide variety of test periods may be selected. For example, for a more corrosive material, a shorter test period may be used (e.g., about 20-60 days), or, for a less corrosive material a longer period may be used (e.g., about 24-120 days). Typically, the test period is about 90 days. At the end of the test period, the coupons are reweighed, and their weight loss for the period is calculated. The corrosion rate is expressed as the weight loss per time period.

This invention relates to an improved coupon holder for corrosion measurement. In particular, the invention relates to a device for eliminating holder-related galvanic corrosion, random positioning of coupons and variable coupon motion in corrosion measurement experiments. Specifically, the holder eliminates common defects in conventional experimental apparatuses that contribute to the corrosion measurements and cause errors in the corrosion data.

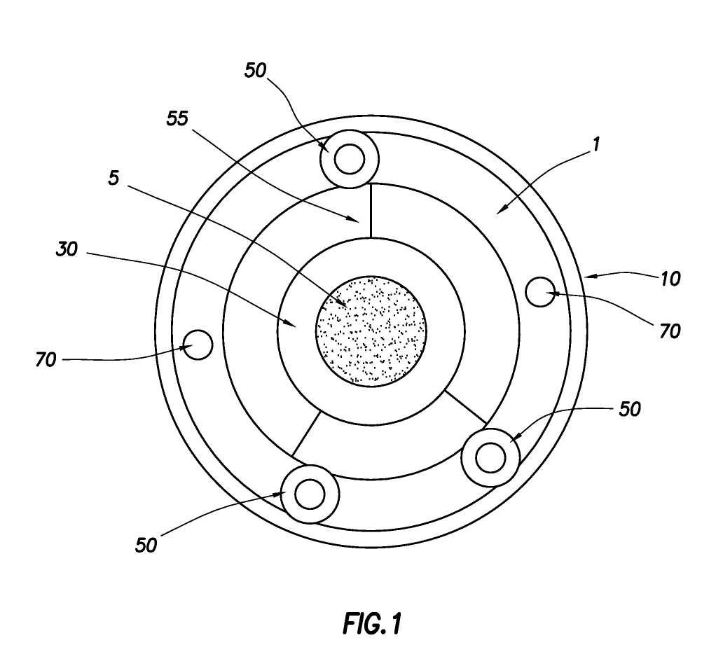

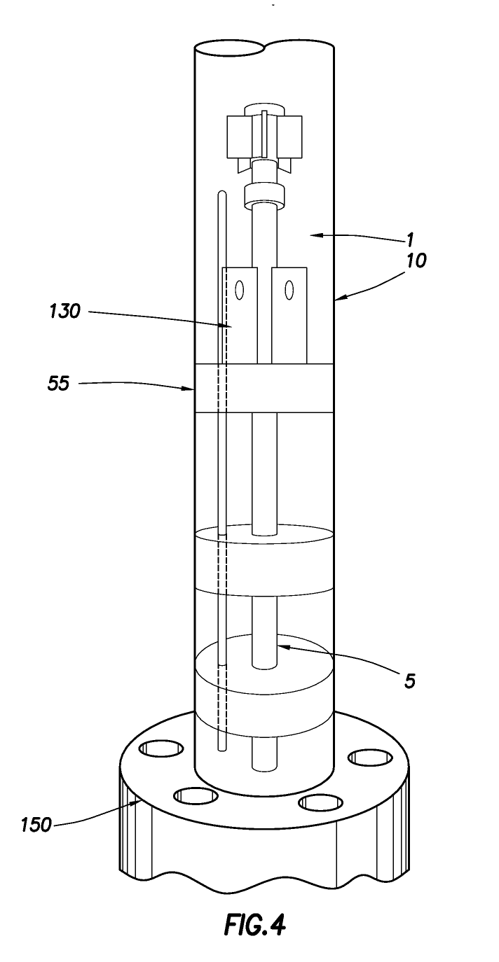

A schematic of an upper end view of a non-metallic coupon holder assembly in a corrosion vessel is shown in FIG. 1. As shown in FIG. 1, the non-metallic coupon holder assembly 1 comprises a non-metallic support structure, a plurality of coupon holders 55, and in this embodiment a bolt opening 30. The plurality of coupon holders can be spaced evenly along the non-metallic support structure. In this figure the non-metallic coupon holder assembly 1 is used in conjunction with a bolt 5 and corrosion vessel 10. In one embodiment the bolt 5 has an attached or is used to attach a stirrer blade. Although it is not shown, the bolt 5 is inserted through the bolt opening 30 into the base plate 150 (shown in FIGS. 4-6) of the corrosion vessel 10.

The corrosion vessel 10 is used to immerse the non-metallic coupon holder assembly into a hydrocarbon fluid in which the metal coupons are being tested.

In one embodiment as shown in FIG. 1 the corrosion vessel assembly 1 may also have ports 70 for guide rods 50 to pass thorough.

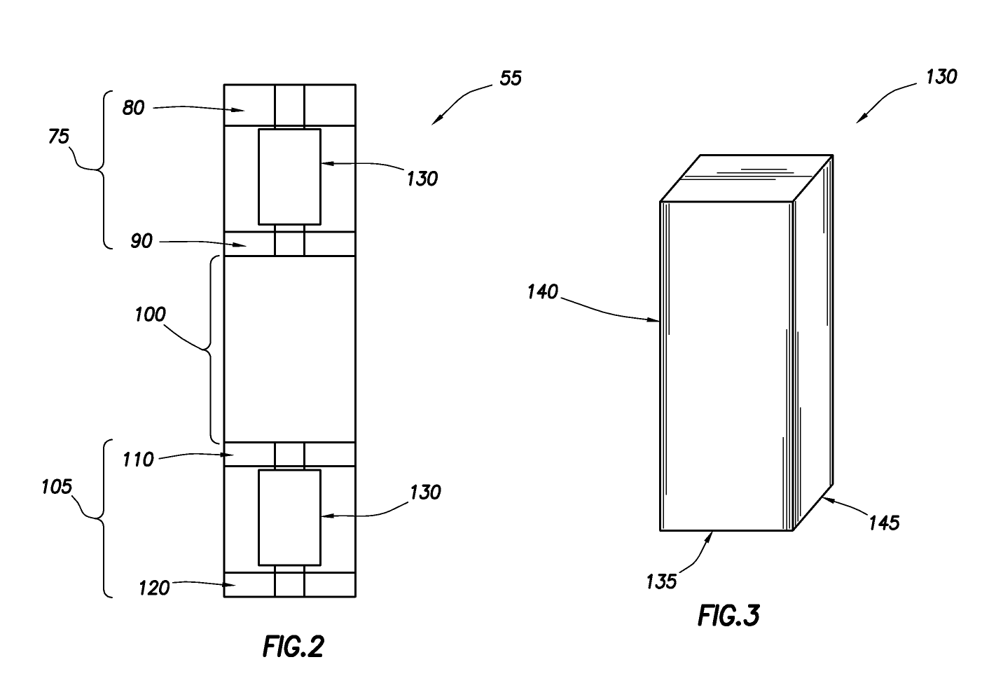

A schematic of a partial side view of a coupon holder assembly in a corrosion vessel is shown in FIG. 2. In this embodiment the non-metallic coupon holder assembly is multi-level with a plurality of coupon holders disposed throughout the non-metallic support structure on each level 75, 105. The non-metallic coupon holder assemblies 75, 105 further comprise upper coupon holders 80, 110 and lower coupon holders 90, 120. As shown in this figure a metal coupon 130 is inserted between the upper coupon holders 80, 110 and lower coupon holders 90, 120.

In one embodiment the spacing of the coupon holders are spaced with a pair of ridges spaced evenly apart at a distance capable of accommodating the thickness of the metal coupon. By having the ridges of the coupon holders spaced at such a distance it prevents any unnecessary movement of the metal coupon while the corrosion test is performed.

A schematic of an elevated side view of a metal coupon is shown in FIG. 3. The metal coupon 130 has a width 135, a length 140 and a thickness 145. In other embodiments the metal coupon can be made from other materials to be corrosion tested. In a preferred embodiment, the metal coupon 130 has a width 135 from about 2 mm to 25 mm, or about 13 mm, a length 140 from about 10 mm to 4 mm or about 25 mm and a thickness 145 from about 0.5 mm to about 3 mm or about 1.5 mm.

Photographs of an elevated side view of a non-metallic coupon holder assembly in a corrosion vessel are shown in FIG. 4. The non-metallic coupon holder assembly 1 is surrounded by a corrosion vessel 10. In this embodiment the metal coupons 130 are held firmly in place with the plurality of coupon holders 55. It is also shown in this embodiment that the non-metallic coupon holder assembly is multi-level with a plurality of coupon holders disposed throughout each level, although only the top level has metal coupons 130 in this embodiment. This non-metallic coupon holder assembly 1 and corrosion vessel 10 are affixed to a base plate 150 wherein a bolt 5 extends through the base plate 150 and the non-metallic coupon holder assembly 1 to aid in the stirring of the hydrocarbon fluid that can be placed inside the corrosion vessel 10 to perform the corrosion test.

As used herein, the terms “a,” “an,” “the,” and “said” means one or more.

As used herein, the term “and/or,” when used in a list of two or more items, means that any one of the listed items can be employed by itself, or any combination of two or more of the listed items can be employed. For example, if a composition is described as containing components A, B, and/or C, the composition can contain A alone; B alone; C alone: A and B in combination; A and C in combination; B and C in combination; or A, B, and C in combination.

As used herein, the terms “comprising,” “comprises,” and “comprise” are open-ended transition terms used to transition from a subject recited before the term to one or elements recited after the term, where the element or elements listed after the transition term are not necessarily the only elements that make up of the subject.

As used herein, the terms “containing,” “contains,” and “contain” have the same open-ended meaning as “comprising,” “comprises,” and “comprise,” provided above.

As used herein, the terms “having,” “has,” and “have” have the same open-ended meaning as “comprising,” “comprises,” and “comprise,” provided above.

As used herein, the terms “including,” “includes,” and “include” have the same open-ended meaning as “comprising,” “comprises,” and “comprise,” provided above.

As used herein, the term “simultaneously” means occurring at the same time or about the same time, including concurrently.

What is claimed is:

1. An apparatus comprising:
a) a non-metallic coupon holder assembly comprising:
i. a non-metallic support structure; and
ii. a plurality of coupon holders disposed throughout the non-metallic support structure wherein the plurality of coupon holders are designed to secure a metal coupon on at least two edges.

2. The apparatus of claim 1, wherein the non-metallic coupon holder assembly is made of quartz.

3. The apparatus of claim 1, wherein the coupon holders comprise a pair of ridges spaced evenly apart at a distance capable of accommodating the thickness of the metal coupon.

4. The apparatus of claim 1, wherein the coupon holders secure both the top edge of the metal coupon and the bottom edge of the metal coupon.

5. The apparatus of claim 1, wherein the plurality of coupon holders are evenly spaced along the non-metallic support structure.

6. The apparatus of claim 1, wherein the non-metallic coupon holder assembly is multi-level with a plurality of coupon holders disposed throughout the non-metallic support structure on each level.

7. An apparatus comprising:
a) a non-metallic coupon holder assembly made of quartz comprising:
i. a non-metallic support structure; and
ii. a plurality of coupon holders disposed throughout the non-metallic support structure wherein the plurality of coupon holders are evenly spaced along the non-metallic support structure and are designed to secure both the top edge of the metal coupon and the bottom edge of the metal coupon and the coupon holders comprise a pair of ridges spaced evenly apart at a distance capable of accommodating the thickness of the metal coupon;
wherein the non-metallic coupon holder assembly is multi-level with a plurality of coupon holders disposed throughout the non-metallic support structure on each level.

8. A method comprising:
a) inserting a metal coupon into a non-metallic coupon holder assembly comprising:
i. a non-metallic support structure; and
ii. a plurality of coupon holders disposed throughout the non-metallic support structure wherein the coupon holders are designed to secure the metal coupon on at least two edges;
b) subjecting the metal coupon to a corrosion test for a specified period of time; and
c) calculating a corrosion rate of the metal coupon by calculating the weight loss of the metal coupon over the specified period of time.

9. The method of claim 8, wherein the non-metallic coupon holder assembly is made of quartz.

10. The method of claim 8, wherein the coupon holders comprise a pair of ridges spaced evenly apart at a distance capable of accommodating the thickness of the metal coupon.

11. The method of claim 8, wherein the coupon holders secure both the top edge of the metal coupon and the bottom edge of the metal coupon.

12. The method of claim 8, wherein the plurality of coupon holders are evenly spaced along the non-metallic support structure.

13. The method of claim 8, wherein the non-metallic coupon holder assembly is multi-level with a plurality of coupon holders disposed throughout the non-metallic support structure on each level.
